(19) United States
(12) Patent Application Publication
(10) Pub. No.: US 2018/0364315 A1
(43) Pub. Date: Dec. 20, 2018

(54) Transformer For Measuring Currents In A Gas-Insulated Substation

(71) Applicant: University of Electronic Science and Technology of China, Chengdu (CN)

(72) Inventors: Qi Huang, Chengdu (CN); Arsalan Habib Khawaja, Islamabad (PK); Yafeng Chen, Chengdu (CN); Shi Jing, Chengdu (CN); Jian Li, Chengdu (CN); Zhenyuan Zhang, Chengdu (CN); Jianbo Yi, Chengdu (CN)

(73) Assignee: University of Electronic Science and Technology of China, Chengdu (CN)

(21) Appl. No.: 15/823,447

(22) Filed: Nov. 27, 2017

(30) Foreign Application Priority Data
Jun. 17, 2017 (CN) 201710446130.1

(51) Int. Cl. G01R 33/09; G01R 19/00; G01R 1/18

(52) U.S. Cl. CPC G01R 33/09; G01R 1/18; G01R 19/0092

(57) ABSTRACT

An electronic current transformer for measuring currents includes a shielding structure, TMR sensor, conductor, amplification circuit, and circuit board. The shielding structure comprises a material that protects the sensor from external disturbance and damps the magnetic field from the internal conductor. The TMR sensor is connected to the amplification circuit for electric current measurement by means of reconstruction of magnetic field measurement. The TMR sensor is configured to receive data from the conductor and to transmit the data to the amplification circuit, which is configured to amplify the data and release the data as an output of the transformer.

### CROSS-REFERENCES TO RELATED APPLICATIONS

This application claims priority from Chinese National Application No. 201710446130.1 filed on Jun. 14, 2017, which is incorporated herein by reference.

### TECHNICAL FIELD OF THE INVENTION

The present invention relates to the field of large current measurement, more particularly to a type of electronic transducer for measuring currents equal to or greater than 100 A in a gas-insulated substation.

### BACKGROUND OF THE INVENTION

Conventional current measurement instruments, including transformers and Rogowski coil-based transducers, are based on magnetic flux induction in winding. Breakthroughs in fabrication technology have resulted in rapid development of linear magnetic sensors. Commonly utilized linear magnetic sensors available as integrated chips are chiefly based upon the Hall effect or spintronic magnetic effect. The Hall effect magnetic sensors demonstrate low sensitivity to an applied magnetic field and therefore utilize flux concentrators when used for current measurement applications. Spintronic sensors are further divided into sensors based upon an Anisotropic Magneto resistive (AMR) effect, Giant Magneto resistive (GMR) effect, and Tunnel Magneto resistive (TMR) effect. AMR sensors can only detect a weak magnetic field strength less than 10 Gauss. The magnetic domain of AMR sensors will become disoriented when exposed to higher field strengths. To remove the disorientation effect, a set/reset pulse is required to calibrate the sensor. The output sensitivity of GMR sensors changes with variations in temperature. For the same effect GMR sensors have a large temperature drift and require remedial processing. It also requires processing for interpretation of bipolar field strengths. On the contrary, the output of recently available commercial TMR sensors is linear over a larger measurement range compared to the aforementioned sensors with smaller intrinsic noise, no sensitivity variation over a range of temperatures and can operate in bipolar mode. This has paved new horizons for application of such sensors in large current measurement.

According to Biot-Savart law, the magnetic field at a known distance from a current-carrying conductor is linearly proportional to the magnitude of the electric current. A magnetic field is concentric to the current-carrying conductor and is distributed radially outwards in all directions. This implies the use of TMR based on a magnetic field sensor for non-contact large current measurement of conductors and bus bars fixed at a known distance from sensing point. One application of current measurement generated from fixed conductor installations include typical gas-insulated switchgears (GIS), where current-carrying conductors are sealed in the metal pipe and casing pipe tree. Another example is an electric arc furnace transformer which is a kind of special transformer for electric arc furnaces for steel melting and is fixed between the furnace and the power network and requires a measurement of current. Some others include high voltage circuit breakers installed in cabinets in a substation. For all such types of conductors, the position of conductors is fixed for the entire life of operation. Thus, a TMR based magnetic field sensor can be installed at a known distance to measure the magnetic flux density and calculate current according to Biot-Savart law. However, if the current is so large in a power system that it's out of the dynamic range of the magnetic field which can be detected by the sensor, the current cannot be measured accurately.

External noise will have an effect on the TMR sensor, which implies magnetic shielding needs to be applied to protect TMR from it. Research is reported by Yaping Du, T. C. Cheng, and A. S. Farag, in their paper titled “Principles of Power-Frequency Magnetic Field Shielding with Flat Sheets in a Source of Long Conductors,” in IEEE TRANSACTIONS ON ELECTROMAGNETIC COMPATIBILITY, VOL. 38, NO. 3, AUGUST 1996. It explains the general principles of magnetic shielding via theoretical analysis. In this work, multiple layers of magnetic shielding of a two-dimensional model are used for experiments. Parameters such as skin depth ratio, relative permeability, and shield location are studied. The authors conclude that the placement of shielding layers and their distance from the sensing point has a significant effect on shielding performance. Furthermore, metals with high permeability are effective as shielding materials.

Further research is provided by Karim Wassef, Vasundara V. Varadan, and Vijay K. Varadan, in their work titled “Magnetic Field Shielding Concepts for Power Transmission Lines in IEEE Transactions on Magnetics,” Vol. 34, No. 3, May 1998. This paper reports the performance of a curved magnetic shielding material with a gap validated by the finite element method. It analyzed the influence of varying gap sizes on shielding effectiveness. By simulations based on the finite element method, the authors point out that an increase in the air gap will improve the shielding effectiveness, and the direction of the gap should be opposite to the interference.

U.S. Pat. No. 5,757,183 discloses a device that shields a magnetic field in a given plane. This device provides a simple magnetic shielding structure, which consists of N annular rings made from a magnetic material of high permeability and N−1 spacer layers made from non-magnetic material. A magnetic sensor is fixed in the structure aligned with the common axis of concentricity of the rings. However, there is no significant research and development on the performance evaluation aspect of shielding layers to attenuate external magnetic interference influence when measurements are performed inside the shielding layers.

TMR sensors have been applied in large current measurement and research has been conducted regarding the usage of multiple layers and a curved layer with a gap for external magnetic interference shielding. However, the method of designing the shielding structure and shielding layers for the external magnetic interference while damping the magnetic field generated by the fixed conductor to enlarge the dynamic measurement range of TMR sensor still remains to be solved.

The present invention includes shielding material that performs both tasks, it protects the sensor from external disturbance and it damps the magnetic field from the internal conductor. A TMR magnetic sensor is connected to amplification circuitry for electric current measurement by means of reconstruction of magnetic field measurement. In order to attenuate external interference influence, the present invention includes multiple magnetic shielding layers made of magnetic material of high permeability, such as Mu metal. Due to the wide band measurement range of the TMR sensor, the invention is able to measure direct and alternating currents. A simple conditioning circuit is designed which consists of an instrumentation amplifier where the gain is adjusted by means of a variable resistor to amplify the TMR sensor output adequately. The circuitry is free from the problems of complex circuits which are seen in conventional electric current measurement instrumentations.

### BRIEF DESCRIPTION OF THE FIGURES

FIG. 1 is an angled side view of the transformer.

FIG. 2 is a top view of the amplification circuit.

FIG. 3 is an angled side view of the transformer with a circular enclosure.

FIG. 4 is a front view of the magnetic flux resulting from a finite element analysis when a strong magnetic interference source is placed at position 1.

FIG. 5 is a diagram of how the transformer measures large currents.

FIG. 6 is a graph of current measurement data based on the strength of the magnetic field.

### BRIEF SUMMARY OF THE EMBODIMENTS OF THE INVENTION

In a variant, an electronic current transformer for measuring currents, comprises a Tunnel Magneto resistive (TMR) sensor, a conductor, an amplification circuit, a shielding structure, and a circuit board. The TMR sensor and amplification circuit are disposed on the circuit board. The circuit board is disposed between the conductor and the shielding structure. The TMR sensor is configured to receive data from the conductor and to transmit the data to the amplification circuit, which is configured to amplify the data and release the data as an output of the transformer.

In another variant, the shielding structure comprises an outer layer, a middle layer, and an inner layer. The outer layer has a circular arc having a greater radius than a circular arc of the middle layer and a circular arc of the inner layer. The middle layer and the inner layer are disposed within an area formed by a chord length and a cross sectional area of the outer layer. The outer layer has a greater width than the middle and inner layers. The outer layer has a center that aligns directly above a center of the middle layer and a center of the inner layer.

In a further variant, the conductor is disposed below the inner layer and aligns with the center of each layer.

In yet another variant, the TMR sensor aligns with the center of each layer.

In another variant, the TMR sensor is disposed within an area formed by a chord length and a cross sectional area of the inner layer.

In a further variant, the TMR sensor is disposed at a test point and measures a magnetic flux density of the conductor at the test point.

In yet another variant, a TMR sensor data output is a voltage value corresponding to the measured magnetic flux density value.

In another variant, the amplification circuit amplifies the voltage and transmits an amplified voltage.

In a further variant, the amplification circuit comprises an instrumentation amplifier and a variable resistor.

In yet another variant, the shielding structure, TMR sensor, and conductor are enclosed by a circular enclosure.

In another variant, an NdFe35 magnet is configured to be an interference source.

In a further variant, the NdFe35 magnet is configured to be disposed at various positions around an exterior of the circular enclosure.

In yet another variant, the TMR sensor is dependent on a reduction in a magnetic field of the conductor.

In another variant, the reduction in the magnetic field of the conductor is dependent on a magnetic flux density with shielding and a magnetic flux density without shielding.

In a further variant, the transformer is configured to measure currents in a gas-insulated substation.

In yet another variant, a second transformer is configured to receive a voltage output from a regulator and convert the voltage output into a current.

In another variant, the conductor is configured to receive the current from the second transformer.

In a further variant, a clamp ammeter and the TMR sensor are configured to measure the current.

### DETAILED DESCRIPTION OF THE EMBODIMENTS OF THE INVENTION

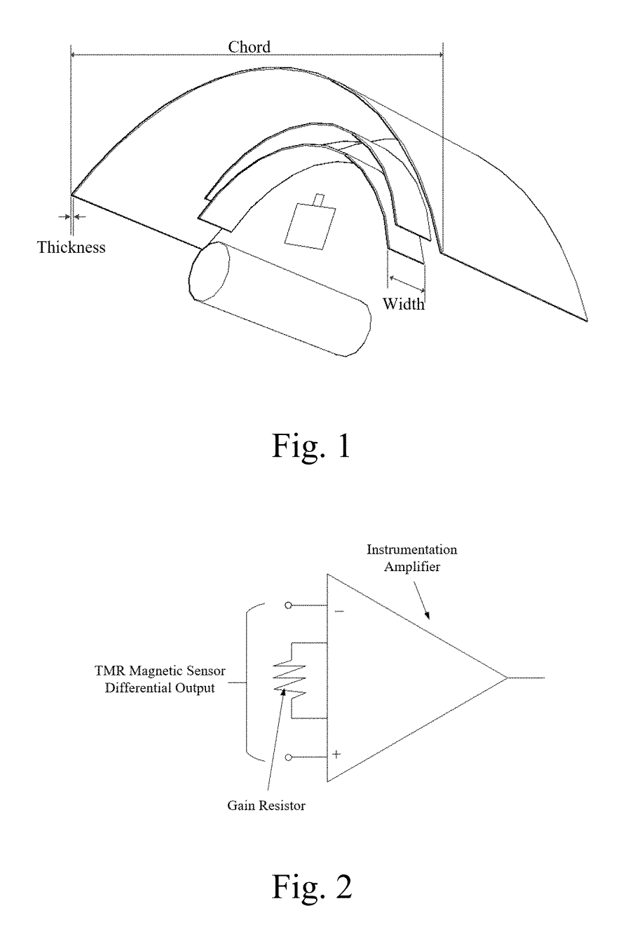

In a variant, referring to FIG. 1, the electronic current transformer comprises a Tunnel Magneto resistive (TMR) sensor, a current-carrying conductor, a mu metal-based magnetic shielding structure, and an amplification circuit. The TMR sensor is located at a test point with a distance of L from the conductor in a radial direction to measure the magnetic flux density generated by the conductor at the test point. The TMR sensor outputs a corresponding sensing voltage to the amplification circuit. The amplification circuit outputs the sensing voltage after amplifying it. The TMR sensor is installed on a circuit board with the amplification circuit and is located in the region formed by the section arc of the innermost shielding layer and its chord.

In another variant, the shielding structure has three layers. Each shielding layer is comprised of highly permeable material that is disposed parallel to the axial direction of the conductor and is bent towards the conductor. The curved section of each shielding layer has a circular arc shape. It is to be noted that the curved cross section described here is a circular arc shape which can also be an approximate arc. Both of them are equivalent. The radius of the section arc of the outer shielding layer is larger than the middle shielding layer and the inner shielding layer (for the approximate arc shape, that is, the curvature degree of the outermost shielding is less curved than the middle layer and the inner layer). The arc length of the cross section of the outer shielding layer is greater than the middle shielding layer and the inner shielding layer. The middle shielding layer and the inner shielding layer are arranged in a region formed by the section arc and the chord of the outer shielding layer. The width of the outer layer (in the direction of the conductor) is greater than the middle shielding layer and the inner layer, respectively. The section arc at the center of each of the three layers is directly aligned above the conductor. The axis of the conductor is coaxial with the outermost shielding layer. In this embodiment, the TMR sensor is also aligned with the section arc center of each of the three shielding layers as shown in FIG. 1.

In a further variant, the structure and the size of the middle layer and the inner layer are exactly the same. The ratio of the surface area of the outer layer to the inner layer is 4:1. Typically, the ratio of the arc length of the outer layer to the inner layer is 1.6:1; the ratio of the width of the outer layer to the inner layer is 2.5:1; and the ratio of the distance between the outer layer and middle layer to the distance between the middle layer and the inner layer is 12:7.

In yet another variant, the TMR sensor can realize non-contact current measurement with high accuracy from a known distance. Non-contact current measurement requires several fixed large current-carrying conductors, such as a gas-insulated switchgear, and bus bars.

In another variant, the shielding layers absorb the magnetic field generated from the conductor under measurement and protect the sensor from external interference. This allows TMR sensor to be utilized for large current of magnitude of hundreds of amperes. The prime objective of the demonstrated magnetic shielding is to protect the sensing region from external magnetic disturbance. It reduces the impact of an external magnetic field to negligible levels to ensure accurate measurements.

In a further variant, referring to FIG. 2, the amplification circuit comprises an instrumentation amplifier, which is a special differential amplifier with high input impedance, extremely good CMRR (Common Mode Rejection Ratio), low input drift, and low output impedance. The instrumentation amplifier can amplify the voltage signal under common mode. After flowing into the positive and negative input of the instrumentation amplifier to be in a proper level by the adjustment of the gain resistance, the differential output of the TMR sensor comes out as the output of the electronic transformer.

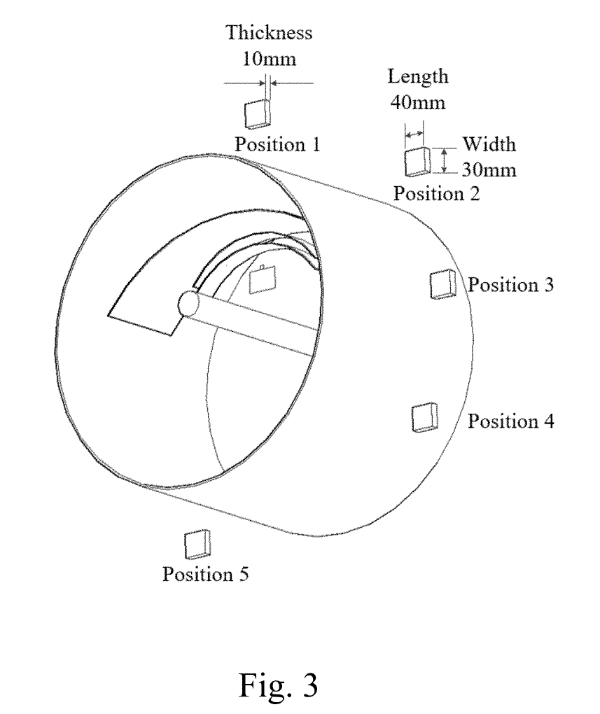

In yet another variant, referring to FIG. 3, the present invention is tested using the Finite Element Analysis (FEA) method in ANSYS Maxwell 16.0 to test the magnetic shielding effect with three sheets of highly permeable mu metal. The model is tested inside air which has a typical earth magnetic flux of 50 micro Tesla in all three directions. A TMR effect-based sensor is utilized at a frequency below 100 KHz. The effective measuring range is 100-1000 Amperes peak to peak current at 50 Hz power frequency. The TMR sensor is fixed away from the innermost shielding layer, located in the center of the shielding layers at a distance which will be confirmed by specific design. In order to demonstrate the effectiveness of this model for a fixed conductor arrangement, it is tested for a portion of a gas-insulated switchgear, where Rogowski coil-based current measurement units are conventionally deployed. A prototype consisting of an enclosure made of stainless steel is designed where a large current-carrying copper conductor runs at its center.

In another variant, the electronic current transformer can be applied in an environment such as a gas-insulated switchgear, where an exposure to a strong magnetic field is inevitable. Non-power frequency can be removed by signal processing techniques. However, when the signal is mixed with a magnetic disturbance at the same frequency, the magnetic field to be measured is affected. To test the shielding performance for an external disturbance of the shielding structure, a strong magnetic material NdFe35 is used to simulate an external disturbance, as an interference source, at various different points around the steel enclosure. NdFe35 has a relative permeability of 1.0998. The critical value of NdFe35 is 0.28 Tesla. The interference source is placed at five different locations outside the external stainless steel enclosure as shown in FIG. 3. Due to the symmetry of the circular arrangement, the effect remains the same when the magnetic interference enters from the other side.

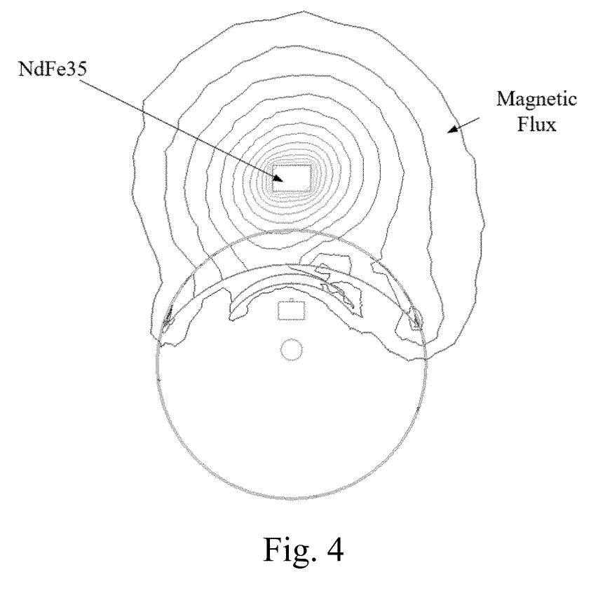

In a further variant, referring to FIG. 4, the magnetic field is measured when the interference source is placed at each position. The sensing region remains unaffected by the presence of the interference. Table 1 presents the measured magnetic field when the interference source is placed at each of the positions.

TABLE 1

| Simulations | | | No interference | Position 1 | Position 2 | Position 3 | Position 4 | Position 5 | Standard Deviation |
|---|---|---|---|---|---|---|---|---|---|
| CURRENT | 100 A | Shielded | 127.71 | 129.93 | 127.96 | 125.64 | 127.76 | 124.34 | 1.96 |
| | | (micro Tesla) | | | | | | | |
| | | Unshielded | 256.29 | 292.85 | 260.62 | 255.04 | 273.86 | 273.91 | 14.44 |
| | | (micro Tesla) | | | | | | | |
| | | DF | 0.50 | 0.44 | 0.49 | 0.49 | 0.47 | 0.45 | 0.02 |
| | 1000 A | Shielded | 950.67 | 960.81 | 964.34 | 956.02 | 965.37 | 963.19 | 5.68 |
| | | (micro Tesla) | | | | | | | |
| | | Unshielded | 2588.06 | 2627.68 | 2557.72 | 2578.87 | 2747.22 | 2604.18 | 67.88 |
| | | (micro Tesla) | | | | | | | |
| | | DF | 0.37 | 0.37 | 0.38 | 0.37 | 0.35 | 0.37 | 0.01 |

The shielding layers not only attenuate the external magnetic interference to negligible levels but also damp the magnetic field by some extent. The extent to which magnetic field from the internal conductor is reduced can be analyzed by the damping factor (DF) which is:

$$DF = \frac{{B}_{s}}{{B}_{u}}$$

In this formula, Bₛ is defined as the magnetic flux density with shielding layers. Bᵤ is defined as the flux without shielding layers. The DF can be used to determine appropriate TMR-based sensors to be employed in such arrangements. From table 1, a conclusion can be made that shielding magnetic layers are feasible for immunity of external disturbance by comparing the standard deviation of shielded and unshielded. As shown in table 1, when the current is 100 A, the magnetic field of the current-carrying conductor is reduced by 50% when there is no external interference. On the same condition, when the current is 1000 A, the magnetic field of the current-carrying conductor is reduced by 37%. In this way, the dynamic measurement range of the TMR sensor is increased.
Based on table 1,

$$Error = \frac{{B}_{1} - {B}_{0}}{{B}_{0}} \times \%$$

is calculated to analyze the effectiveness of the magnetic shielding against external disturbances. The results are shown in table 2. Here, it is evident that magnetic interference without shielding layers significantly increase the measurement error. When the magnetic interference source is placed at position 1, the error rises up to 14.25% whereas with shielding layers it remains less than 3%.

TABLE 2
Measurement Error (%)

| Simulations | | Position 1 | Position 2 | Position 3 | Position 4 | Position 5 |
|---|---|---|---|---|---|---|
| Current = 100 A | Unshielded | 14.27 | 1.69 | 0.49 | 6.86 | 6.88 |
| | Shielded | 1.74 | 0.19 | 1.62 | 0.04 | 2.63 |
| Current = 1000 A | Unshielded | 1.53 | 1.17 | 0.35 | 6.15 | 0.62 |
| | Shielded | 1.07 | 1.44 | 0.56 | 1.55 | 1.32 |

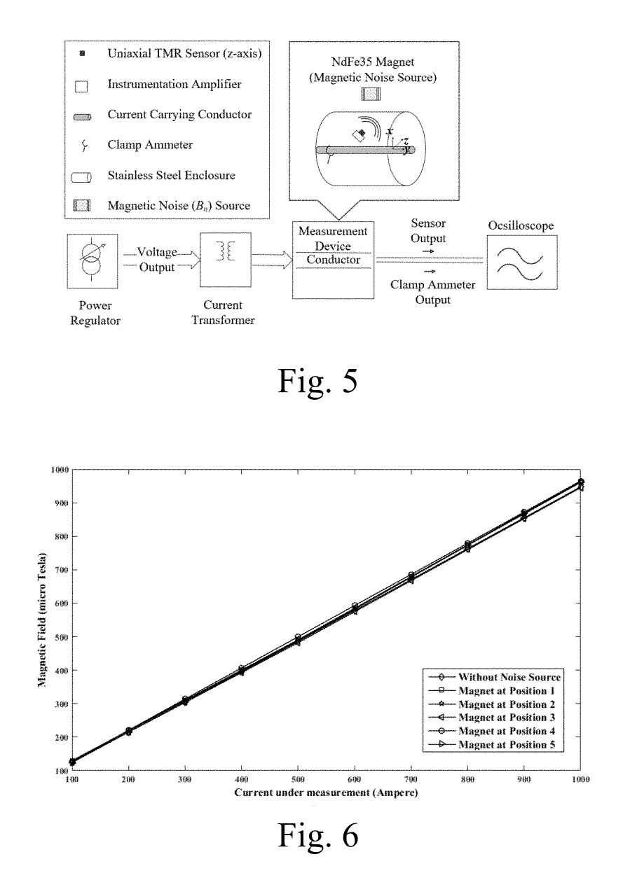

In yet another variant, referring to FIG. 5, experimental validation is carried out to confirm the results from the Finite Element Analysis. Dimensions of all entities and environment parameters are the same as those of the Finite Element Analysis.

Under the voltage output of the regulator, a specially-made transformer will generate a large current to a measurement device, which includes the electronic transformer applied in large current measurements in a gas-insulated substation. The large current will be loaded to the current-carrying conductor. Meanwhile, the clamp ammeter measures the current. The output of the clamp ammeter and TMR sensor are transmitted into the oscilloscope to observe the results. The output of the TMR sensor is linear with the interference of a strong magnetic field. The steps of the experiment are as follows: perform a magnetic field measurement at current 100 A without any interference; repeat the experiment in the presence of the interference source, i.e., NdFe35 Magnet of magnitude 0.28 Tesla, in five different positions; increase the current by 100 A using the power regulator; and repeat the second step.

In another variant, referring to FIG. 6, the results from the experimental setup are summarized, where the slope for each set of measurements from 100 A to 1000 A remains similar to the other sets. The present invention is not limited to current measurement at power frequency in a gas-insulated switchgear. As the responding frequency range of TMR sensor can be up to megahertz, it can be used for measurement under different frequencies with a similar instrumentation amplifier.

The examples and tests are only presented to clearly present the usefulness of the method. The present invention is not limited to current measurement at a power frequency in a gas-insulated switchgear. Since the TMR sensor has a frequency response from DC to several megahertz, an instrumentation amplifier with similar characteristics may be utilized for measurements at other frequencies. This invention describes the utilization of highly permeable mu metal, not only to shield sensitive equipment but also to perform measurements by means of an advanced magneto resistive sensor.

What is claimed is:

1. An electronic current transformer for measuring currents, comprising:
a Tunnel Magneto resistive (TMR) sensor;
a conductor;
an amplification circuit;
a shielding structure;
a circuit board;
wherein the TMR sensor and amplification circuit are disposed on the circuit board;
wherein the circuit board is disposed between the conductor and the shielding structure; and
wherein the TMR sensor is configured to receive data from the conductor and to transmit the data to the amplification circuit, which is configured to amplify the data and release the data as an output of the transformer.

2. The transformer of claim 1, wherein the shielding structure comprises:
an outer layer;
a middle layer;
an inner layer;
wherein the outer layer has a circular arc having a greater radius than a circular arc of the middle layer and a circular arc of the inner layer;
wherein the middle layer and the inner layer are disposed within an area formed by a chord length and a cross sectional area of the outer layer;
wherein the outer layer has a greater width than the middle and inner layers; and
wherein the outer layer has a center that aligns directly above a center of the middle layer and a center of the inner layer.

3. The transformer of claim 2, wherein the conductor is disposed below the inner layer and aligns with the center of each layer.

4. The transformer of claim 2, wherein the TMR sensor aligns with the center of each layer.

5. The transformer of claim 2, wherein the TMR sensor is disposed within an area formed by a chord length and a cross sectional area of the inner layer.

6. The transformer of claim 1, wherein the TMR sensor is disposed at a test point and measures a magnetic flux density of the conductor at the test point.

7. The transformer of claim 1, wherein a TMR sensor data output is a voltage value corresponding to the measured magnetic flux density value.

8. The transformer of claim 7, wherein the amplification circuit amplifies the voltage and transmits an amplified voltage.

9. The transformer of claim 1, wherein the amplification circuit comprises an instrumentation amplifier and a variable resistor.

10. The transformer of claim 1, wherein the shielding structure, TMR sensor, and conductor are enclosed by a circular enclosure.

11. The transformer of claim 10, wherein an NdFe35 magnet is configured to be an interference source.

12. The transformer of claim 11, wherein the NdFe35 magnet is configured to be disposed at various positions around an exterior of the circular enclosure.

13. The transformer of claim 1, wherein the TMR sensor is dependent on a reduction in a magnetic field of the conductor.

14. The transformer of claim 13, wherein the reduction in the magnetic field of the conductor is dependent on a magnetic flux density with shielding and a magnetic flux density without shielding.

15. The transformer of claim 1, wherein the transformer is configured to measure currents in a gas-insulated substation.

16. The transformer of claim 15, wherein a second transformer is configured to receive a voltage output from a regulator and convert the voltage output into a current.

17. The transformer of claim 16, wherein the conductor is configured to receive the current from the second transformer.

18. The transformer of claim 17, wherein a clamp ammeter and the TMR sensor are configured to measure the current.
